(19) United States
(12) Patent Application Publication
(10) Pub. No.: US 2024/0297463 A1
(43) Pub. Date: Sep. 5, 2024

(54) CONNECTOR ASSEMBLY

(71) Applicant: MOLEX, LLC, Lisle, IL (US)

(72) Inventor: Che-Yuan Yang, New Taipei City (TW)

(21) Appl. No.: 18/438,525

(22) Filed: Feb. 12, 2024

(30) Foreign Application Priority Data
Mar. 3, 2023 (CN) 202310202519.7

(51) Int. Cl. H01R 13/6582; H01R 12/72; H01R 13/506

(52) U.S. Cl. CPC H01R 13/6582; H01R 12/721; H01R 13/506

(57) ABSTRACT

A connector assembly includes a guide shielding cage, a heat sink bracket and at least two heat sink modules. The guide shielding cage includes a top wall, two side walls, a partitioning wall which is positioned between the two side walls, and at least two mating channels which are sideward arranged side by side and are partitioned by the partitioning wall. The heat sink bracket is assembled to the top wall of the guide shielding cage, the partitioning wall of the guide shielding cage extends into the heat sink bracket to constitute at least two accommodating cavities which correspond to the at least two mating channels, the partitioning wall has a first wall portion which is positioned in the guide shielding cage and a second wall portion which is positioned in the heat sink bracket, the partitioning wall and the heat sink bracket are therebetween assembled by a first assembling construction, the heat sink bracket and the top wall of the guide shielding cage are assembled by a second assembling construction. The at least two heat sink modules are respectively assembled in the at least two accommodating cavities of the heat sink bracket.

### RELATED APPLICATION

The present application claims priority to Chinese patent application no. 202310202519.7 filed on Mar. 3, 2023, which is incorporated by reference in its entirety.

### TECHNICAL FIELD

The present disclosure relates to a connector assembly, and particularly relates to a connector assembly which has a heat sink.

### BACKGROUND

Chinese patent document CN114623722A (corresponding to United States patent document US2022/0190506A1) discloses a heat sink module which includes a heat dissipating member, pressure applying elastic members, a lever member and supporting elastic members. The heat sink module is entirely accommodated in an upper heat sink bracket, the lever member is pivoted to the upper heat sink bracket, the lever member is used to downwardly apply a pressure to the pressure applying elastic members, the pressure applying elastic members push the heat dissipating member to move downwardly, after an acting force of the lever member is released, the supporting elastic members are used to elastically support the heat dissipating member to move upwardly. However, there is only single upper heat sink bracket disclosed in this patent document, when such a heat sink bracket needs to be applied to a guide shielding cage which has a plurality of mating channels, in order to accommodate a plurality of heat sink modules at the same time, the heat sink bracket needs to be redesigned in construction.

### SUMMARY

Therefore, an object of the present disclosure is to provide a connector assembly which can improve at least one problem of prior art.

Accordingly, in some embodiments, a connector assembly of the present disclosure comprises a guide shielding cage, a heat sink bracket and at least two heat sink modules. The guide shielding cage comprises a top wall, two side walls, a partitioning wall which is positioned between the two side walls, and at least two mating channels which are sideward arranged side by side and are partitioned by the partitioning wall. The heat sink bracket is assembled to the top wall of the guide shielding cage, the partitioning wall of the guide shielding cage extends into the heat sink bracket to constitute at least two accommodating cavities which correspond to the at least two mating channels, the partitioning wall has a first wall portion which is positioned in the guide shielding cage and a second wall portion which is positioned in the heat sink bracket, the partitioning wall and the heat sink bracket are therebetween assembled by a first assembling construction, the heat sink bracket and the top wall of the guide shielding cage are assembled by a second assembling construction. The at least two heat sink modules are respectively assembled in the at least two accommodating cavities of the heat sink bracket.

In some embodiments, the first assembling construction comprises a lower latching construction which is between the second wall portion of the partitioning wall and a bottom plate of the heat sink bracket and an upper latching construction which is between the second wall portion of the partitioning wall and a top plate of the heat sink bracket.

In some embodiments, the lower latching construction comprises a forward extending latch piece and a rearward extending latch piece, the forward extending latch piece extends forwardly from the second wall portion and is used to latch with the bottom plate of the heat sink bracket, the rearward extending latch piece extends rearwardly from the second wall portion, sideward bends offset and is used to latch with the bottom plate of the heat sink bracket; the upper latching construction comprises an upper latching piece which extends upwardly from an upper edge of the second wall portion and is used to pass through a latching slit formed to the top plate to latch with the top plate of the heat sink bracket.

In some embodiments, the lower latching construction further comprises a pair of bendable latching pieces which are between the forward extending latch piece and the rearward extending latch piece and are used to latch with the bottom plate of the heat sink bracket.

In some embodiments, the top plate is further formed with a depressed portion which is depressed downwardly, the latching slit of the top plate is formed to a bottom portion of the depressed portion, the upper latching piece of the upper latching construction passes through the latching slit of the top plate and is positioned in the depressed portion.

In some embodiments, the second assembling construction comprises a side latching construction which is between a left side and right side of a bottom plate of the heat sink bracket and a left side and right side of the top wall of the guide shielding cage, a side plate latching construction which is between side plates of the heat sink bracket and the two side walls of the guide shielding cage, and a rear latching construction which is between a rear end of the bottom plate of the heat sink bracket and the top wall of the guide shielding cage.

In some embodiments, the side latching construction comprises a snapping piece which extends out of the top wall and a protruding piece which extends sideward from the bottom plate of the heat sink bracket, the snapping piece has a snapping groove which is opened forwardly and is used to snap the protruding piece of the heat sink bracket.

In some embodiments, the side plate latching construction comprises inserting pieces which extend from the side plates of the heat sink bracket to outer sides of the side wall of the guide shielding cage and protrude rearwardly, bulges which are formed to the side walls, and inserting holes which are constructed to the bulges and are opened forwardly, the inserting pieces are used to rearwardly insert into the inserting holes.

In some embodiments, the rear latching construction comprises a rear latching piece which extends downwardly from a rear end of the bottom plate of the heat sink bracket and a rear latching groove which is formed to the top wall of the guide shielding cage, the rear latching piece is used to downwardly latch to the rear latching groove.

In some embodiments, the second assembling construction further comprises a sideward limiting-position construction which is between two sides of the bottom plate of the heat sink bracket and the two side walls of the guide shielding cage.

In some embodiments, the sideward limiting-position construction comprises side limiting-position pieces which bend downwardly from rear ends of the two sides of the bottom plate of the heat sink bracket and extend, the side limiting-position pieces are respectively positioned at outer side surfaces of the two side walls of the guide shielding cage.

In some embodiments, the heat sink module comprises a heat sink, force applying springs, a rotatable member and supporting springs; the rotatable member acts to the force applying springs, the force applying springs downwardly act to the heat sink, the supporting springs elastically upwardly support the heat sink.

In some embodiments, the rotatable member of the heat sink module has pivoting shafts, the pivoting shafts of the rotatable members of the two adjacent heat sink modules are front and rear staggered, the second wall portion of the partitioning wall has two pivoting holes which are front and rear staggered and are used to be respectively pivoted with the pivoting shafts of the two adjacent rotatable members.

In the present disclosure, the at least two accommodating cavities of the heat sink bracket are respectively used to accommodate the at least two heat sink modules, and the guide shielding cage and the heat sink bracket share the partitioning wall(s). The partitioning wall(s) and the heat sink bracket are therebetween assembled by the first assembling construction, the heat sink bracket and the top wall of the guide shielding cage are assembled by the second assembling construction, so the heat sink bracket is capable of being firmly assembled on the guide shielding cage. In addition, the pivoting shafts of the adjacent two rotatable members of the heat sink modules are front and rear staggered, so the adjacent two rotatable members are capable of being pivoted to the same partitioning wall.

### BRIEF DESCRIPTION OF THE DRAWINGS

Other features and effects of the present disclosure will be apparent from an embodiment with reference to the drawings, in which:

FIG. 1 is a perspective view of an embodiment of a connector assembly of the present disclosure, a circuit board and a pluggable module;

FIG. 2 is a perspective exploded view of the embodiment;

FIG. 3 is a further perspective exploded view of the embodiment;

FIG. 4 is a perspective exploded view of a guide shielding cage of the embodiment;

FIG. 5 is a perspective view of the guide shielding cage and a heat sink bracket of the embodiment;

FIG. 6 is a perspective view of the guide shielding cage and the heat sink bracket of the embodiment viewed from another angle;

FIG. 7 is a partially enlarged perspective view of a region A of FIG. 5 illustrating a lower latching construction and an upper latching construction of a first assembling construction of the embodiment;

FIG. 8 is a partially enlarged perspective view of a region B of FIG. 6 illustrating the lower latching construction and the upper latching construction of the first assembling construction and a rear latching construction of a second assembling construction of the embodiment;

FIG. 9 is a partially enlarged perspective view of a region C of FIG. 5 illustrating a side latching construction of the second assembling construction of the embodiment;

FIG. 10 is a partially enlarged perspective view of a region D of FIG. 5 illustrating a side plate latching construction and a sideward limiting-position construction of the second assembling construction of the embodiment;

FIG. 11 is a perspective exploded view of the heat sink bracket and heat sink modules of the embodiment;

FIG. 12 is a perspective exploded view of the heat sink bracket and the heat sink modules of the embodiment viewed from another angle.

### DETAILED DESCRIPTION

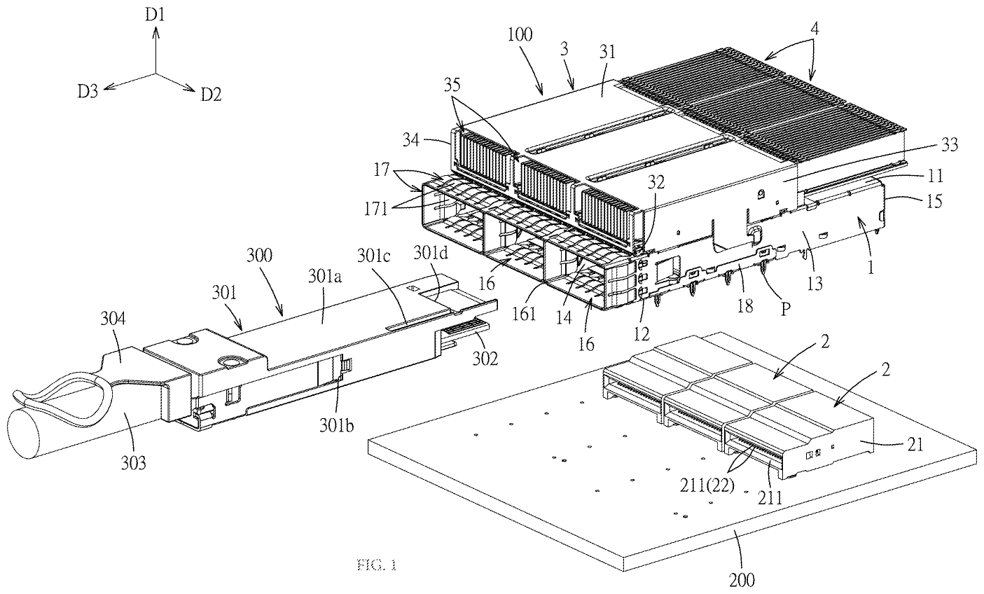

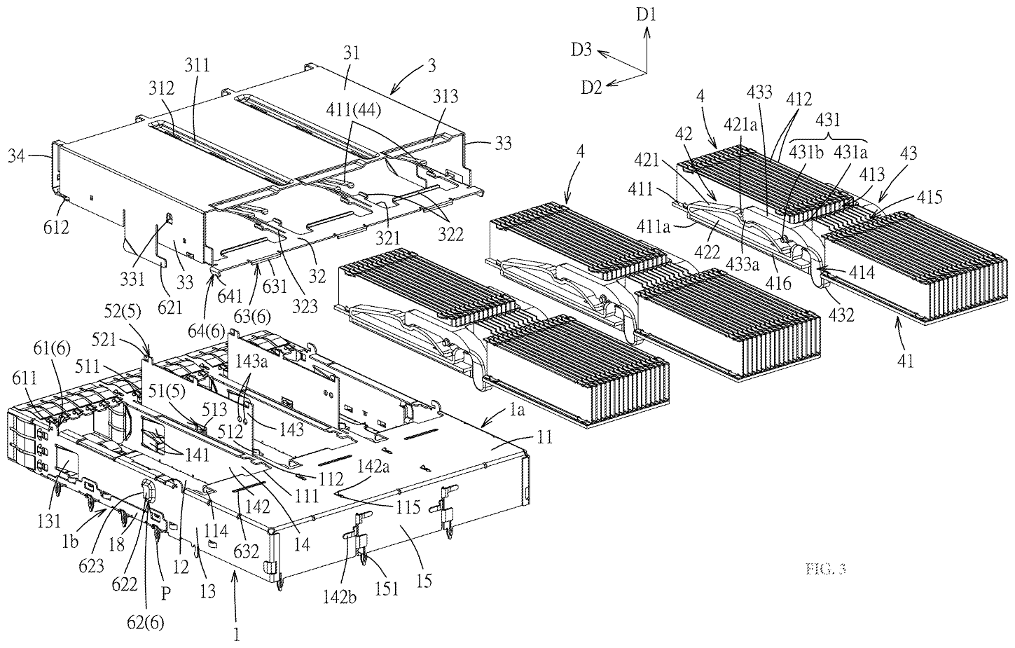

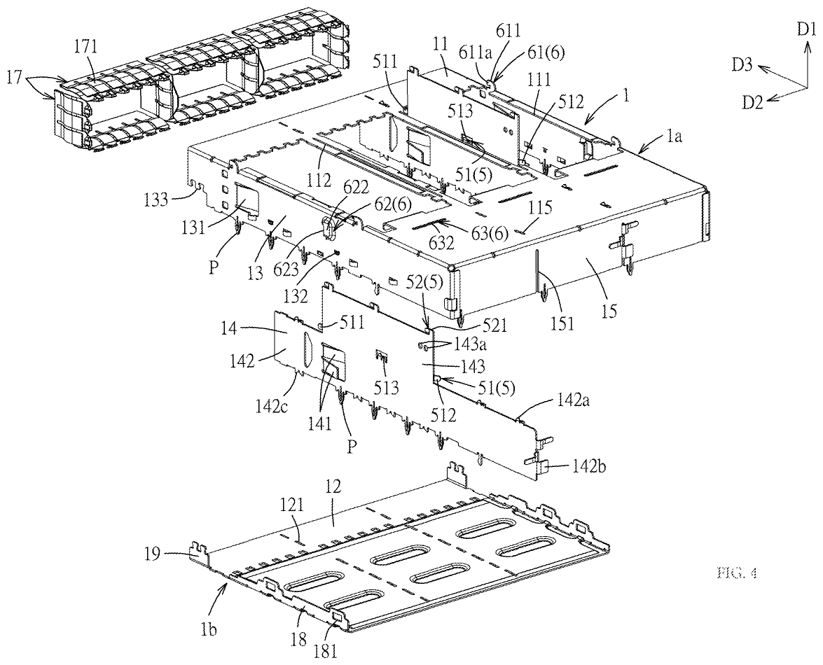

Referring to FIG. 1 to FIG. 4, an embodiment of a connector assembly 100 of the present disclosure is adapted to be provided on a circuit board 200, and is adapted to mate with a pluggable module 300. The pluggable module 300 has a shell member 301, a mating circuit board 302 and a cable 303. The shell member 301 has an inserting portion 301a, the mating circuit board 302 is provided to a front end of the inserting portion 301a, the cable 303 is provided to a rear end of the shell member 301 and is electrically connected to the mating circuit board 302. The connector assembly 100 includes a guide shielding cage 1, three receptacle connectors 2, a heat sink bracket 3 and three heat sink modules 4. It is noted that, the number of the receptacle connectors 2 corresponds to the number of the heat sink modules 4, in other implementing manners, the number of the receptacle connector 2 and the number of the heat sink module 4 also each may be two or more, and thus are not limited to the present embodiment.

The guide shielding cage 1 is for example formed by processing, such as stamping and bending, a metal thin plate via a mold, the guide shielding cage 1 is used to be provided to the circuit board 200. The guide shielding cage 1 has a top wall 11 and a bottom wall 12 which are spaced apart from each other along an up-down direction D1 (a direction to which an arrow points is up, and an opposite direction is down), two side walls 13 which are spaced apart from each other along a left-right direction D2 (a direction to which an arrow points is right, and an opposite direction is left), two partitioning walls 14 which are positioned between the two side walls 13, a rear wall 15 which is positioned to a rear end of the guide shielding cage 1 along a front-rear direction D3 (a direction to which an arrow points is front, and an opposite direction is rear), three mating channels 16 which are left and right sideward arranged side by side, are positioned inside the guide shielding cage 1 and are partitioned by the two partitioning walls 14, and a plurality of inserting legs P which extend downwardly from low edges of the two side walls 13, low edges of the two partitioning walls 14 and a low edge of the rear wall 15 and are adapted to be fixed on the circuit board 200 and/or connected to ground trace (not shown). Each mating channel 16 has a front end inserting port 161 which is toward the front and allows the inserting portion 301a of the pluggable module 300 to insert therein and a bottom opening 162 which is positioned at a rear of a bottom portion of the mating channel 16. It is noted that, the number of the partitioning wall 14 also may be one or more, and the number of the mating channels 16 also may be two or more according to the different number of the partitioning wall 14, which is not limited to the present embodiment.

The top wall 11 of the guide shielding cage 1 has windows 111 which are respectively communicated with the mating channels 16, first slits 112 which are positioned between the mating channels 16 and front and rear extend, guiding portions 113 which each extend downwardly from a rear segment of a side of the corresponding window 111 into the corresponding mating channel 16, and stopping portions 114 which each extend downwardly from a rear end of the corresponding window 111 into the corresponding mating channel 16. Each side wall 13 of the guide shielding cage 1 has an inward extending elastic piece 131 which is positioned in the front of the side wall 13 and extends into the adjacent mating channel 16. Each partitioning wall 14 of the guide shielding cage 1 has two inward extending elastic pieces 141 which are positioned in the front of the partitioning wall 14 and respectively extend into the two adjacent mating channels 16.

Ground members 17 are assembled around the front end inserting ports 161 of the mating channels 16 of the guide shielding cage 1. In the present embodiment, the guide shielding cage 1 of the connector assembly 100 may be provided to a mounting hole (not shown) of a casing (not shown), each ground member 17 has a plurality of elastic portions 171 which extend rearwardly and are distributed to an outer side and an inner side of the guide shielding cage 1, the elastic portion 171 which is positioned at the outer side of the guide shielding cage 1 is used to contact a peripheral part of the mounting hole of the casing, the elastic portion 171 which is positioned at the inner side of the guide shielding cage 1 is used to contact the pluggable module 300.

The receptacle connectors 2 are used to be arranged side by side along the left-right direction D2 and be provided on the circuit board 200, the receptacle connectors 2 each are received in a rear segment of the corresponding mating channel 16 via the bottom opening 162 of the corresponding mating channel 16 of the guide shielding cage 1. Each receptacle connector 2 has a housing 21 which is insulative and a plurality of terminals 22 which are provided to the housing 21. The housing 21 has a mating slot 211 which allows the mating circuit board 302 of the pluggable module 300 to insert therein, each terminal 22 has a contact portion 221 which is positioned in the mating slot 211 and a tail portion (not shown) which extends downwardly out of a bottom portion of the housing 21, the tail portions of the plurality of terminals 22 are respectively used to be soldered to pads (not shown) on the circuit board 200 so as to connect conductive traces (not shown) on the circuit board 200.

The inserting portion 301a of the pluggable module 300 has two locking recessed grooves 301b which are respectively positioned at a left side and a right side of the inserting portion 301a, a guiding groove structure 301c which is positioned to a top portion of the front end of the inserting portion 301a, and an aligning structure 301d which is positioned a top portion of the inserting portion 301a. The inward extending elastic pieces 131 of the two side walls 13 and the inward extending elastic pieces 141 of the partitioning walls 14 of the guide shielding cage 1 are used to cooperate with the two locking recessed grooves 301b of the pluggable module 300 which inserts into the corresponding mating channel 16, so as to generate a locking effect. The guiding portion 113 is used to insert into the guiding groove structure 301c of the pluggable module 300 so as to generate a guiding function. The stopping portion 114 is used to stop the aligning structure 301d of the pluggable module 300 so as to limit an inserting position of the pluggable module 300. In addition, the pluggable module 300 further has a locking release member 304, when the locking release member 304 is pulled, the inward extending elastic piece 131 and the inward extending elastic piece 141 can be pushed out of the locking recessed groove 301b.

The heat sink bracket 3 is assembled on the top wall 11 of the guide shielding cage 1. The heat sink bracket 3 has a top plate 31 and a bottom plate 32 which are spaced apart from each other along the up-down direction D1, two sides plates 33 which are spaced apart from each other along the left-right direction D2, and a front connecting plate 34 which is positioned to a front end of the heat sink bracket 3 along the front-rear direction D3 and is connected between the top plate 31 and the bottom plate 32. The bottom plate 32 has frame openings 321 which correspond to the windows 111, support protruding bars 322 which integrally extend upwardly from peripheries of the frame openings 32 respectively, and second slits 323 which correspond to the first slits 112 and are positioned above the first slits 112 respectively. The top plate 31 has depressed portions 311 which are depressed downwardly, correspond to the second slits 323 and are positioned above the second slits 323 respectively, and latching slits 312 which are respectively formed to bottom portions of the depressed portions 311. The partitioning walls 14 of the guide shielding cage 1 respectively pass through the first slits 112 of the top wall 11 and the second slits 323 of the bottom plate 32 to extend into the heat sink bracket 3, so as to constitute three accommodating cavities 35 in the heat sink bracket 3 which correspond to the three mating channels 16 respectively, and top portions of the partitioning walls 14 of the guide shielding cage 1 correspondingly snap into the latching slits 312 of the top plate 31. It is noted that, the number of the accommodating cavities 35 correspond to the number of the mating channels 16 and also may be two or more. Each partitioning wall 14 integrally has a first wall portion 142 which is positioned in the guide shielding cage 1 and a second wall portion 143 which upwardly passes through the corresponding first slit 112 and the corresponding second slit 323 to be positioned in the heat sink bracket 3.

In addition, in the present embodiment, the guide shielding cage 1 includes an upper shell 1a and a lower shell 1b which are assembled with each other. The upper shell 1a has the top wall 11, the two side walls 13 and the rear wall 15 which are integrally connected with each other, a plurality of latching blocks 132 which are close to low edges of the two side walls 13, protrude outwardly and are formed to the two side walls 13, and two dovetail recesses 133 which are respectively formed to bottom edges of the two side walls 13 close to front ends of the two side walls 13. The lower shell 1b has the bottom wall 12, two sides assembling plates 18 which integrally extend upwardly from two sides of the bottom wall 12, a plurality of latching holes 181 which are formed to the two sides assembling plates 18 and correspond to the plurality of latching blocks 132 of the two side walls 13, and two dovetail protrusions 19 which are integrally formed upwardly from the bottom wall 12 close to the front end of the bottom wall 12 and correspondingly cooperate with the two dovetail recesses 133 of the two side walls 13. The two sides assembling plates 18 of the lower shell 1b are respectively positioned at outer side surfaces of the two side walls 13 of the upper shell 1a, the plurality of latching holes 181 of the two sides assembling plates 18 latch to the plurality of latching blocks 132 of the two side walls 13 respectively, so that the bottom wall 12 of the lower shell 1b is capable of being assembled and engaged with the two side walls 13 of the upper shell 1a. The first wall portion 142 of each partitioning wall 14 has a plurality of pairs of first bendable latching pieces 142a which extends upwardly from a top portion of the first wall portion 142 and pass through first latching holes 115 of the top wall 11 of the guide shielding cage 1, a plurality of groups of second bendable latching piece 142b which extend rearwardly from a rear end of the first wall portion 142 and pass through a plurality of second latching holes 151 of the rear wall 15, and a pair of third bendable latching pieces 142c which extend downwardly from a bottom portion of the first wall portion 142 and pass through a corresponding third latching hole 121 of the bottom wall 12 of the guide shielding cage 1. Each pair of first bendable latching pieces 142a are used to sideward bend opposite to each other so as to latch with the top wall 11 of the guide shielding cage 1, each group of second bendable latching pieces 142b are used to sideward bend so as to latch with the rear wall 15 of the guide shielding cage 1, the pair of third bendable latching pieces 142c are used to sideward bend opposite to each other so as to latch with the bottom wall 12 of the guide shielding cage 1.

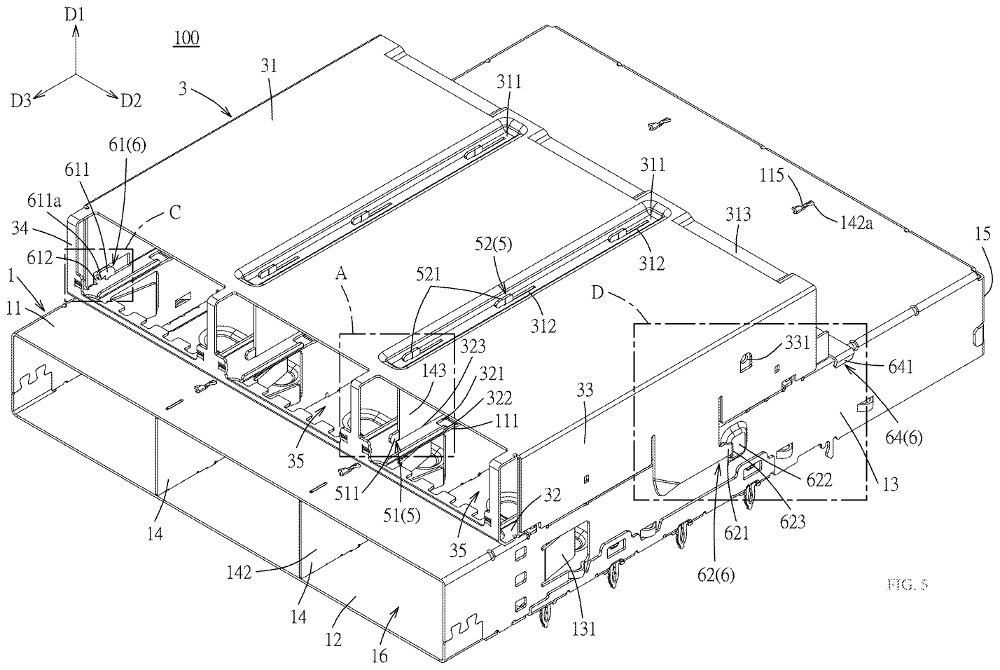

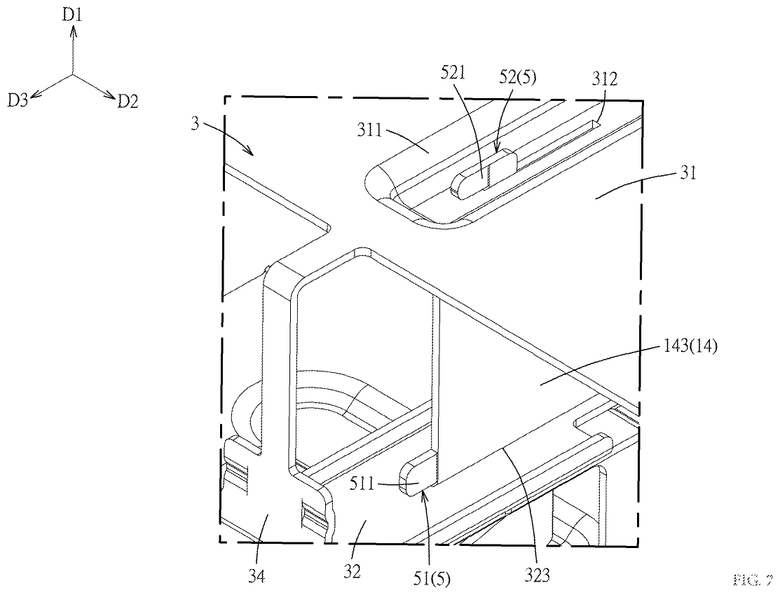

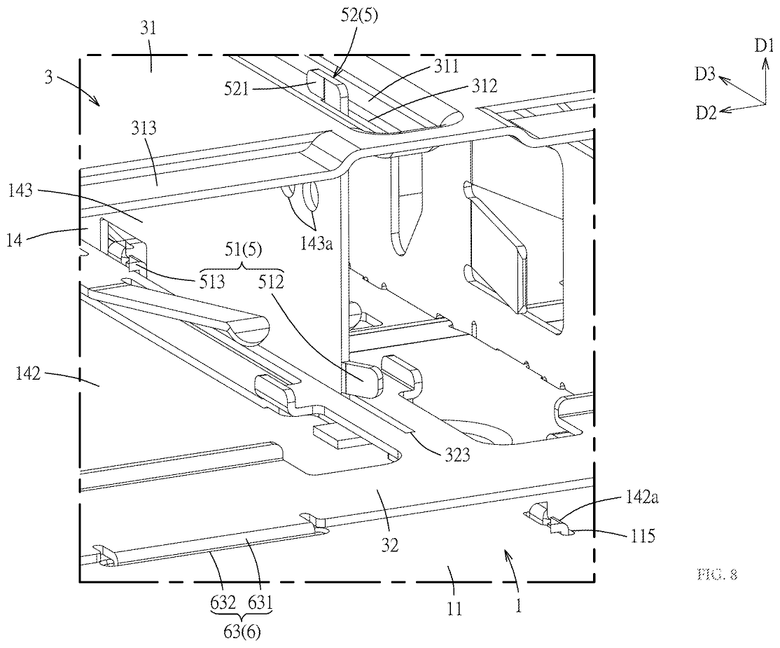

Referring to FIG. 5 to FIG. 8, the partitioning walls 14 and the heat sink bracket 3 are therebetween assembled by a first assembling construction 5, the heat sink bracket 3 and the top wall 11 of the guide shielding cage 1 are assembled by a second assembling construction 6. The first assembling construction 5 includes a lower latching construction 51 which is between the second wall portion 143 of each partitioning wall 14 and the bottom plate 32 of the heat sink bracket 3 and an upper latching construction 52 which is between the second wall portion 143 of each partitioning wall 14 and the top plate 31 of the heat sink bracket 3.

The lower latching construction 51 is adjacent to the bottom plate 32 of the heat sink bracket 3 and is positioned above the bottom plate 32. The lower latching construction 51 includes a forward extending latch piece 511, a rearward extending latch piece 512, and a pair of bendable latching pieces 513. The forward extending latch piece 511 extends forwardly from a front end of the second wall portion 143 of each partitioning wall 14 and is used to latch with the bottom plate 32 of the heat sink bracket 3, the rearward extending latch piece 512 extends rearwardly from a rear end of the second wall portion 143 of each partitioning wall 14 and sideward bend offset to be used to latch with the bottom plate 32 of the heat sink bracket 3, the pair of bendable latching pieces 513 are between the forward extending latch piece 511 and the rearward extending latch piece 512, and are used to sideward bend opposite to each other so as to latch with the bottom plate 32 of the heat sink bracket 3.

The upper latching construction 52 includes a plurality of upper latching pieces 521 which extend upwardly from an upper edge of the second wall portion 143 of each partitioning wall 14 and are used to pass through the corresponding latching slits 312 of the top plate 31 so as to latch with the top plate 31 of the heat sink bracket 3, in the present preferred embodiment, the plurality of upper latching pieces 521 of the upper latching construction 52 pass through the corresponding latching slits 312 of the top plate 31 and are positioned in the corresponding depressed portion 311, the plurality of upper latching pieces 521 may not protrude from the top wall 11. It is noted that, in other implementing manners, the plurality of upper latching pieces 521 of the upper latching construction 52 also may be incompletely positioned in the corresponding depressed portion 311, and each depressed portion 311 of the top plate 31 also may be omitted.

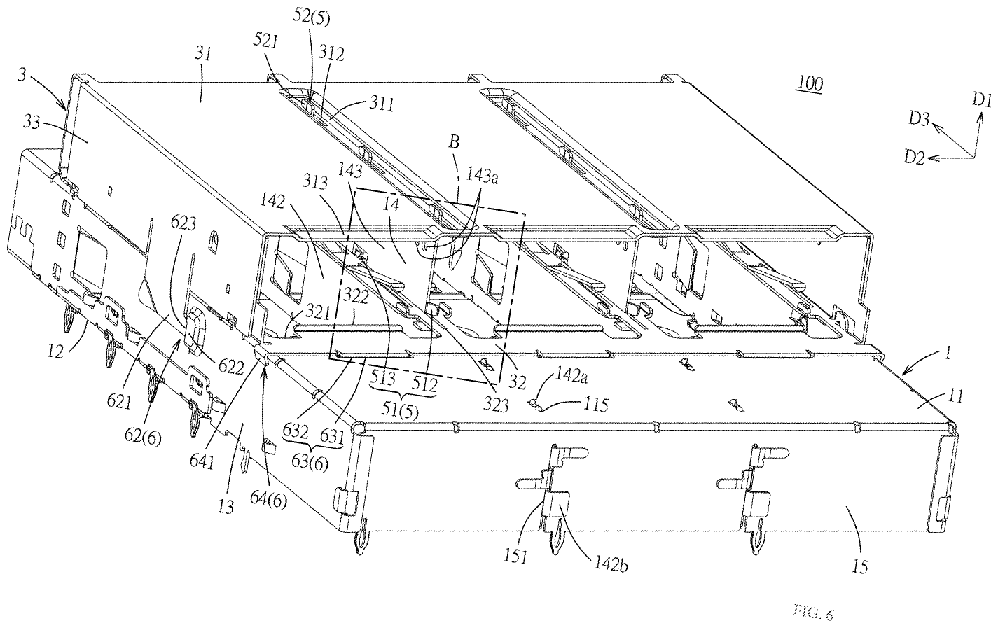

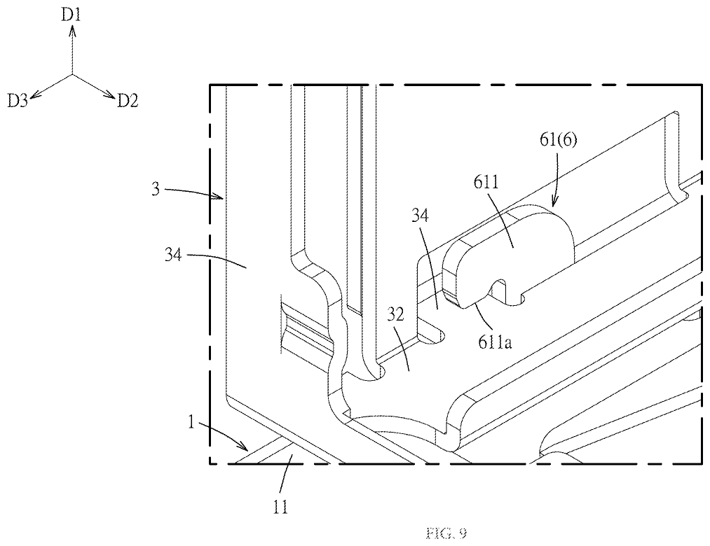

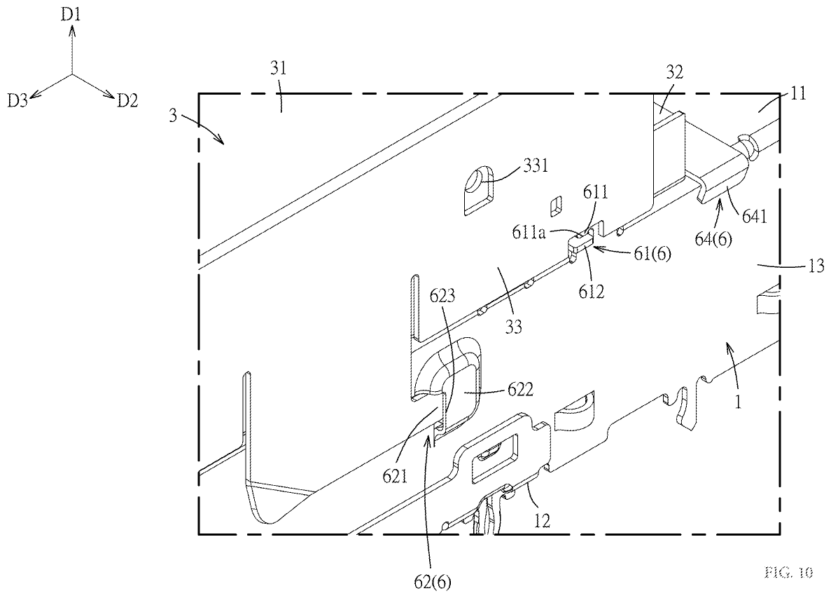

Referring to FIG. 5, FIG. 6, FIG. 9 and FIG. 10, the second assembling construction 6 includes a side latching construction 61 which is between a left side and right side of the bottom plate 32 of the heat sink bracket 3 and a left side and right side of the top wall 11 of the guide shielding cage 1, a side plate latching constructions 62 which is between the two sides plates 33 of the heat sink bracket 3 and the two side walls 13 of the guide shielding cage 1, a rear latching construction 63 which is between a rear end of the bottom plate 32 of the heat sink bracket 3 and the top wall 11 of the guide shielding cage 1, and a sideward limiting-position construction 64 which is between the two sides of the bottom plate 32 of the heat sink bracket 3 and the two side walls 13 of the guide shielding cage 1.

The side latching construction 61 includes a plurality of snapping pieces 611 which extend out of the top wall 11 and are adjacent to the two side walls 13 and a plurality of protruding pieces 612 which extend sideward from the bottom plate 32 of the heat sink bracket 3 and respectively correspond to the plurality of snapping pieces 611, each snapping piece 611 has a snapping groove 611a which is opened forwardly and is used to snap the corresponding protruding piece 612 of the heat sink bracket 3.

The side plate latching construction 62 includes two inserting pieces 621 which extend respectively from the two sides plates 33 of the heat sink bracket 3 to outer sides of the two side walls 13 of the guide shielding cage 1 and protrude rearwardly, two bulges 622 which are respectively formed to the two side walls 13 of the guide shielding cage 1, and inserting holes 623 which each are respectively constructed to a front side of the corresponding bulge 622 and are opened forwardly, the two inserting pieces 621 are respectively used to rearwardly insert into the two inserting holes 623 so as to respectively snap into the two bulges 622.

The rear latching construction 63 includes a plurality of rear latching pieces 631 which extend downwardly from the rear end of the bottom plate 32 of the heat sink bracket 3 and a plurality of rear latching grooves 632 which are formed to the top wall 11 of the guide shielding cage 1 and respectively correspond to the plurality of rear latching pieces 631, the plurality of rear latching pieces 631 are respectively used to downwardly latch to the plurality of rear latching grooves 632.

The sideward limiting-position construction 64 includes two side limiting-position pieces 641 which respectively bend downwardly from rear ends of the two sides of the bottom plate 32 of the heat sink bracket 3, the two side limiting-position pieces 641 are respectively position at the outer side surfaces of the two side walls 13 of the guide shielding cage 1, and are used to limit a position of the heat sink bracket 3 relative to the guide shielding cage 1 in the left-right direction D2.

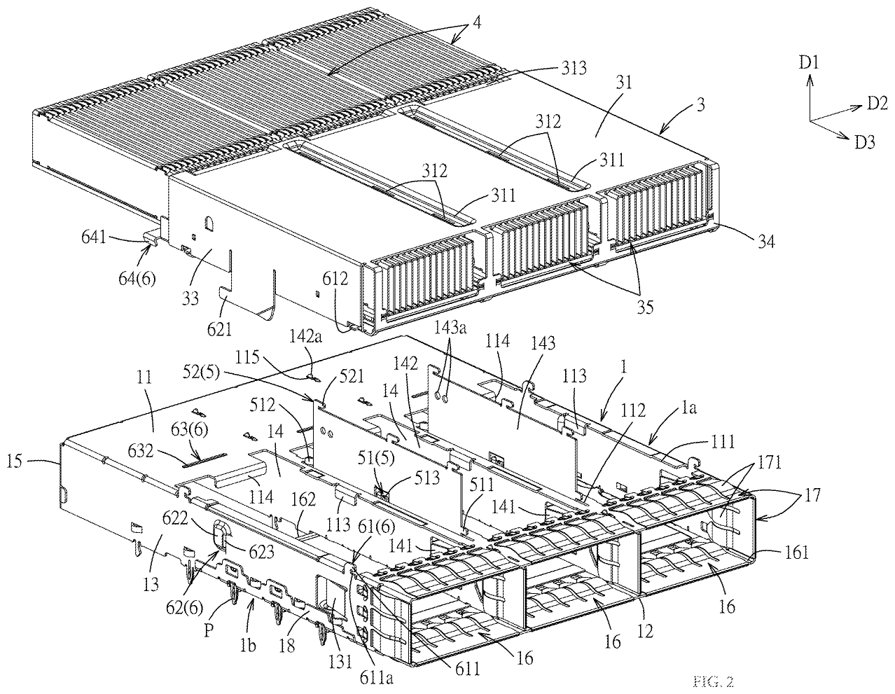

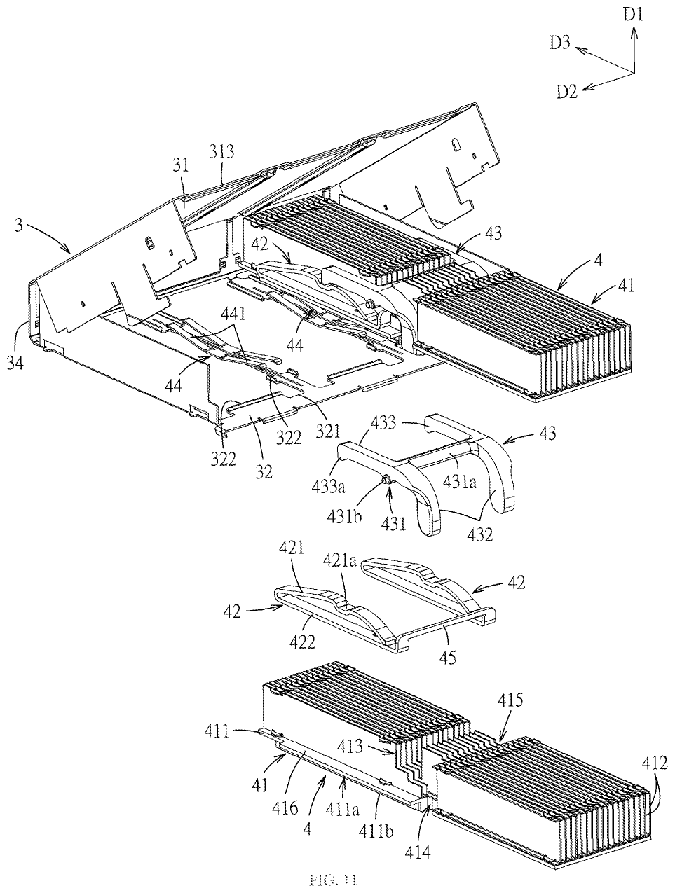

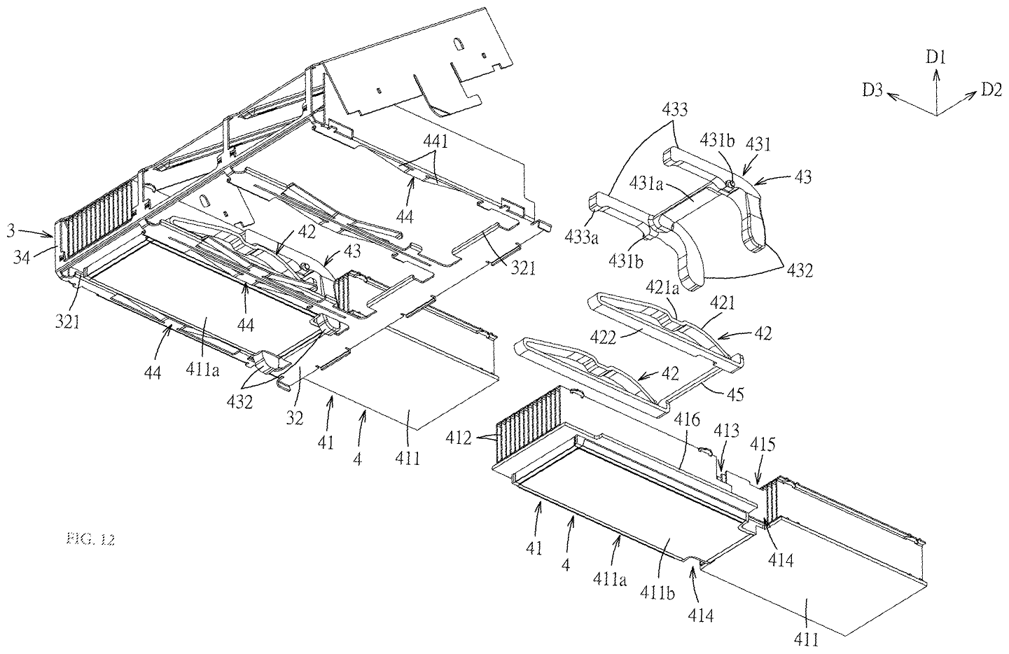

Referring to FIG. 1, FIG. 2, FIG. 11 and FIG. 12, the heat sink modules 4 are respectively assembled in the accommodating cavities 35 of the heat sink bracket 3 so as to respectively correspond to the mating channels 16. Each heat sink module 4 includes a heat sink 41, two force applying springs 42, a rotatable member 43 and two supporting springs 44. The heat sink 41 has a base plate 411, a plurality of heat dissipating fins 412 which are arranged side by side in the left-right direction D2, latch with each other and are provided to a top surface of the base plate 411 by for example welding, a first groove 413 which extends in the left-right direction D2 and is formed to the plurality of heat dissipating fins 412, two second grooves 414 which extend in the up-down direction D1, are positioned behind the first groove 413 and are respectively formed to a left side and a right side of the heat sink 41, a third groove 415 which extends in the left-right direction D2, is positioned behind the first groove 413 and is formed to the plurality of heat dissipating fins 412, and two force applying spring acting portions 416 which protrude outwardly from a left side edge and a right side edge of a front segment of the base plate 411 respectively and extend along the front-rear direction D3. A depth of the third groove 415 is shallow relative to a depth of the first groove 413, and the third groove 415 correspondingly receives a rear frame bar 313 which is positioned at a rear end of the top plate 31 of the heat sink bracket 3 and extends in the left-right direction D2, by that the third groove 415 and the rear frame bar 313 cooperate with each other can limit the heat sink 41 to move in the front-rear direction D3. Each force applying spring acting portion 416 is constructed as a sideward protruding plate which protrudes sideward from the corresponding side edge of the base plate 411 (that is, at the down of a side surface of the heat sink 41) and front and rear extends. It is noted that, in a varied embodiment, the plurality of heat dissipating fins 412 also may be integrally formed upwardly from the top surface of the base plate 411.

The base plate 411 has a thermal coupling portion 411a which is downwardly formed, the thermal coupling portion 411a is used to pass through the corresponding frame opening 321 and the corresponding window 111, so as to contact the pluggable module 300 inserting into the corresponding mating channel 16 and transfer heat from the pluggable module 300, thereby promoting heat dissipating performance of the heat sink module 4. The thermal coupling portion 411a are limited in position in the front-rear direction D3 and the left-right direction D2 by the frame opening 321, the window 111 and the support protruding bars 322, so the heat sink 41 basically can be limited to only move in the up-down direction D1 so as to make the heat sink 41 be capable of moving between a non-operating position which is positioned in the up and an operating position which is positioned in the down. In the present embodiment, the thermal coupling portion 411a includes a thermal conductive pad 411b which is positioned to a bottom portion of the thermal coupling portion 411a and is used to contact the pluggable module 300. The thermal conductive pad 411b for example may be a thermal interface material, and the thermal interface material may be selected from, for example, a combination of materials with performances, such as high thermal conductivity, high flexibility, compressibility, insulation, abrasion resistance, etc. al, and for example, can be a combination of a substrate and a phase change material.

The two force applying springs 42 are respectively positioned at two sides of the heat sink 41 and are respectively used to act to the two force applying spring acting portions 416. Each force applying spring 42 has an elastic arm 421 and a bottom arm 422 which extend along the front-rear direction D3. The elastic arm 421 and the bottom arm 422 of each force applying spring 42 are integrally constructed and are connected with each other, the elastic arm 421 rearwardly bends back from a front end of the bottom arm 422. The elastic arm 421 is positioned above the bottom arm 422, and a rear end of the elastic arm 421 downwardly abuts and acts to a rear end of the bottom arm 422 and is used to downwardly act to the bottom arm 422. The rear ends of the bottom arms 422 of the two force applying springs 42 therebetween are integrally constructed and connected with a transverse connecting arm 45, the transverse connecting arm 45 is received in the first groove 413 of the heat sink 41. The elastic arm 421 of each force applying spring 42 has a rotatable member acting portion 421a which is positioned in the middle of the elastic arm 421, the rotatable member acting portion 421a is for example constructed as a recess. The bottom arms 422 of the two force applying springs 42 are respectively used to downwardly act to the two force applying spring acting portions 416 of the heat sink 41.

The rotatable member 43 has a pivoting portion 431, two first rods 432 which are arranged side by side along the left-right direction D2 and extend downwardly from the pivoting portion 431, and two second rods 433 which are arranged side by side along the left-right direction D2 and extend forwardly from the pivoting portion 431. In the present embodiment, the pivoting portion 431 has a transverse rod 431a which extends along the left-right direction D2 and is received in the first groove 413 of the heat sink 41 and two pivoting shafts 431b which respectively extend from outer sides of the pivoting portion 431 along the left-right direction D2. Specifically, the pivoting shafts 431b of the rotatable members 43 of the two adjacent heat sink modules 4 are front and rear staggered, the second wall portion 143 of each partitioning wall 14 has two pivoting holes 143a which are front and rear staggered and are used to be pivoted with the pivoting shafts 431b of the two adjacent rotatable member 43, each side plate 33 has one pivoting hole 331 which is used to be pivoted with one pivoting shaft 431b of the adjacent rotatable member 43. By that the pivoting shafts 431b and the pivoting holes 143a and the pivoting holes 331 are therebetween pivoted and cooperate with each other, the rotatable member 43 is capable of rotating between a first position and a second position.

The two first rods 432 are used to sequentially pass through the two second grooves 414 of the heat sink 41, the frame opening 321 and the window 111 and extend into the mating channel 16. Tips of the two second rods 433 are respectively used to act to the rotatable member acting portions 421a of the elastic arms 421 of the two force applying springs 42, each second rod 433 has a protrusion 433a which is positioned to a tip of the second rod 433 and correspondingly cooperates with and is positioned in the recess constructed by the rotatable member acting portion 421a.

The two supporting springs 44 are respectively positioned at two sides of the corresponding frame opening 321 and are integrally constructed to the bottom plate 32 of the heat sink bracket 3, and the two supporting springs 44 are respectively positioned at two sides of the down of the corresponding heat sink 41, so as to elastically upwardly support the two force applying spring acting portions 416 of the heat sink 41. Each supporting spring 44 has two supporting elastic pieces 441 which obliquely extend upwardly toward the front and toward the rear respectively. It is noted that, in other implementing manners, the supporting spring 44 also may be an independent component and is assembled on the heat sink bracket 3 by welding or latching. Here, top portions of the support protruding bars 322 are higher than connected locations between the two supporting springs 44 and the heat sink bracket 3, when the heat sink 41 is pressed down to a position where the heat sink 41 contacts the support protruding bars 322, the support protruding bars 322 is capable of assisting in supporting the heat sink 41, at the same time preventing the two supporting springs 44 from being excessively pressed down by the heat sink 41 to generate deformation.

When the pluggable module 300 does not insert into the mating channel 16, the rotatable member 43 is in the first position, the two first rods 432 of the rotatable member 43 extend into the mating channel 16, and the heat sink 41 is in the non-operating position due to supporting from the two supporting springs 44, the thermal coupling portion 411a of the heat sink 41 does not extend into the mating channel 16.

When the pluggable module 300 inserts into the mating channel 16 of the guide shielding cage 1 from front to rear via the front end inserting port 161, the pluggable module 300 supplies an external force to push the two first rods 432 of the rotatable member 43, in turn push the rotatable member 43 to gradually rotate from the first position to the second position, at this time the two first rods 432 of the rotatable member 43 are relatively away from the mating channel 16, and the two second rods 433 of the rotatable member 43 respectively act to the elastic arms 421 of the two force applying springs 42, the elastic arms 421 of the two force applying springs 42 which are pressed and downwardly deformed downwardly act to the bottom arms 422 of the two force applying springs 42, so as to bring the bottom arms 422 of the two force applying springs 42 to downwardly and directly act to the two force applying spring acting portions 416 of the heat sink 41 respectively, after forces downwardly applied to the heat sink 41 by the two force applying springs 42 are larger than upward supporting forces of the two supporting springs 44 and the two supporting springs 44 are downwardly compressed, the heat sink 41 gradually moves downwardly from the non-operating position to the operating position, in this state, the thermal coupling portion 411a of the heat sink 41 extends into the mating channel 16 via the window 111 and contacts a surface of the pluggable module 300 with contacting pressure. Subsequently, when the pluggable module 300 is withdrawn from the mating channel 16, the external force subjected by the rotatable member 43 is released, the two supporting springs 44 restore from the compressed state and upwardly raise the heat sink 41, to make the heat sink 41 move upwardly from the operating position to the non-operating position, and to bring the rotatable member 43 to rotate back from the second position to the first position via the two force applying springs 42, and in turn make the two first rods 432 of the rotatable member 43 extend into the mating channel 16 again.

In conclusion, in the present disclosure, the at least two accommodating cavities 35 of the heat sink bracket 3 are respectively used to accommodate the at least two heat sink modules 4, and the guide shielding cage 1 and the heat sink bracket 3 share the partitioning wall(s) 14. The partitioning wall(s) 14 and the heat sink bracket 3 are therebetween assembled by the first assembling construction 5, the heat sink bracket 3 and the top wall 11 of the guide shielding cage 1 are assembled by the second assembling construction 6, so the heat sink bracket 3 is capable of being firmly assembled on the guide shielding cage 1. In addition, the pivoting shafts 431b of the adjacent two rotatable members 43 of the heat sink modules 4 are front and rear staggered, so the adjacent two rotatable members 43 are capable of being pivoted to the same partitioning wall 14.

However, the above description is only for the embodiment of the present disclosure, and it is not intended to limit the implementing scope of the present disclosure, and the simple equivalent changes and modifications made according to the claims and the contents of the specification are still included in the scope of the present disclosure.

What is claimed is:

1. A connector assembly comprising:
a guide shielding cage comprising a top wall, two side walls, a partitioning wall which is positioned between the two side walls, and at least two mating channels which are sideward arranged side by side and are partitioned by the partitioning wall;
a heat sink bracket assembled to the top wall of the guide shielding cage, the partitioning wall of the guide shielding cage extending into the heat sink bracket to constitute at least two accommodating cavities which correspond to the at least two mating channels, the partitioning wall having a first wall portion which is positioned in the guide shielding cage and a second wall portion which is positioned in the heat sink bracket, the partitioning wall and the heat sink bracket being therebetween assembled by a first assembling construction, the heat sink bracket and the top wall of the guide shielding cage being assembled by a second assembling construction; and
at least two heat sink modules being respectively assembled in the at least two accommodating cavities of the heat sink bracket.

2. The connector assembly of claim 1, wherein
the first assembling construction comprises a lower latching construction which is between the second wall portion of the partitioning wall and a bottom plate of the heat sink bracket and an upper latching construction which is between the second wall portion of the partitioning wall and a top plate of the heat sink bracket.

3. The connector assembly of claim 2, wherein
the lower latching construction comprises a forward extending latch piece and a rearward extending latch piece, the forward extending latch piece extends forwardly from the second wall portion and is used to latch with the bottom plate of the heat sink bracket, the rearward extending latch piece extends rearwardly from the second wall portion, sideward bends offset and is used to latch with the bottom plate of the heat sink bracket;
the upper latching construction comprises an upper latching piece which extends upwardly from an upper edge of the second wall portion and is used to pass through a latching slit formed to the top plate to latch with the top plate of the heat sink bracket.

4. The connector assembly of claim 3, wherein
the lower latching construction further comprises a pair of bendable latching pieces which are between the forward extending latch piece and the rearward extending latch piece and are used to latch with the bottom plate of the heat sink bracket.

5. The connector assembly of claim 3, wherein
the top plate is further formed with a depressed portion which is depressed downwardly, the latching slit of the top plate is formed to a bottom portion of the depressed portion,
the upper latching piece of the upper latching construction passes through the latching slit of the top plate and is positioned in the depressed portion.

6. The connector assembly of claim 1, wherein
the second assembling construction comprises a side latching construction which is between a left side and right side of a bottom plate of the heat sink bracket and a left side and right side of the top wall of the guide shielding cage, a side plate latching construction which is between side plates of the heat sink bracket and the two side walls of the guide shielding cage, and a rear latching construction which is between a rear end of the bottom plate of the heat sink bracket and the top wall of the guide shielding cage.

7. The connector assembly of claim 6, wherein
the side latching construction comprises a snapping piece which extends out of the top wall and a protruding piece which extends sideward from the bottom plate of the heat sink bracket,
the snapping piece has a snapping groove which is opened forwardly and is used to snap the protruding piece of the heat sink bracket.

8. The connector assembly of claim 6, wherein
the side plate latching construction comprises inserting pieces which extend from the side plates of the heat sink bracket to outer sides of the side wall of the guide shielding cage and protrude rearwardly, bulges which are formed to the side walls, and inserting holes which are constructed to the bulges and are opened forwardly,
the inserting pieces are used to rearwardly insert into the inserting holes.

9. The connector assembly of claim 6, wherein
the rear latching construction comprises a rear latching piece which extends downwardly from a rear end of the bottom plate of the heat sink bracket and a rear latching groove which is formed to the top wall of the guide shielding cage,
the rear latching piece is used to downwardly latch to the rear latching groove.

10. The connector assembly of claim 6, wherein
the second assembling construction further comprises a sideward limiting-position construction which is between two sides of the bottom plate of the heat sink bracket and the two side walls of the guide shielding cage.

11. The connector assembly of claim 10, wherein
the sideward limiting-position construction comprises side limiting-position pieces which bend downwardly from rear ends of the two sides of the bottom plate of the heat sink bracket and extend, the side limiting-position pieces are respectively positioned at outer side surfaces of the two side walls of the guide shielding cage.

12. The connector assembly of claim 1, wherein
the heat sink module comprises a heat sink, force applying springs, a rotatable member and supporting springs;
the rotatable member acts to the force applying springs, the force applying springs downwardly act to the heat sink, the supporting springs elastically upwardly support the heat sink.

13. The connector assembly of claim 12, wherein
the rotatable member of the heat sink module has pivoting shafts,
the pivoting shafts of the rotatable members of the two adjacent heat sink modules are front and rear staggered,
the second wall portion of the partitioning wall has two pivoting holes which are front and rear staggered and are used to be respectively pivoted with the pivoting shafts of the two adjacent rotatable members.
